(19) United States
(12) Patent Application Publication
(10) Pub. No.: US 2024/0178325 A1
(43) Pub. Date: May 30, 2024

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP)

(73) Assignee: Japan Display Inc., Tokyo (JP)

(21) Appl. No.: 18/519,392

(22) Filed: Nov. 27, 2023

(30) Foreign Application Priority Data
Nov. 28, 2022 (JP) 2022-189329

(51) Int. Cl. H01L 29/786; H01L 29/06

(52) U.S. Cl. CPC H01L 29/7869; H01L 29/0603; H01L 29/78696

(57) ABSTRACT

A semiconductor device includes an oxide insulating layer, an oxide semiconductor layer on the oxide insulating layer, a gate insulating layer on and in contact with the oxide semiconductor layer, and a gate electrode on the gate insulating layer. The oxide semiconductor layer includes a channel region overlapping the gate electrode, and source and drain regions that do not overlap the gate electrode. At an interface between the source and drain regions and the gate insulating layer, a concentration of an impurity on a surface of at least one of the source and drain regions is greater than or equal to 1×10¹⁹ cm⁻³.

### CROSS-REFERENCE TO RELATED APPLICATIONS

This application claims the benefit of priority to Japanese Patent Application No. 2022-189329, filed on Nov. 28, 2022, the entire contents of which are incorporated herein by reference.

### FIELD

An embodiment of the present invention relates to a semiconductor device using an oxide semiconductor as a channel.

### BACKGROUND

In recent years, a semiconductor device in which an oxide semiconductor is used for a channel instead of a silicon semiconductor such as amorphous silicon, low-temperature polysilicon, and single-crystal silicon, etc. has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). A semiconductor device including such an oxide semiconductor can be formed with a simple structure and a low-temperature process, similar to a semiconductor device including amorphous silicon. The semiconductor device including the oxide semiconductor is known to have higher field effect mobility than the semiconductor device including amorphous silicon.

### SUMMARY

A semiconductor device according to an embodiment of the present invention includes an oxide insulating layer, an oxide semiconductor layer on the oxide insulating layer, a gate insulating layer on and in contact with the oxide semiconductor layer, and a gate electrode on the gate insulating layer. The oxide semiconductor layer includes a channel region overlapping the gate electrode, and source and drain regions that do not overlap the gate electrode. At an interface between the source and drain regions and the gate insulating layer, a concentration of an impurity on a surface of at least one of the source and drain regions is greater than or equal to 1×10¹⁹ cm⁻³.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a schematic partially enlarged sectional view showing a configuration of a semiconductor device according to an embodiment of the present invention.

FIG. 4 is a flow chart showing a method of manufacturing a semiconductor device according to an embodiment of the present invention.

FIG. 5 is a schematic cross-sectional view showing a method of manufacturing a semiconductor device according to an embodiment of the present invention.

FIG. 6 is a schematic cross-sectional view showing a method of manufacturing a semiconductor device according to an embodiment of the present invention.

FIG. 7 is a schematic cross-sectional view showing a method of manufacturing a semiconductor device according to an embodiment of the present invention.

FIG. 8 is a schematic cross-sectional view showing a method of manufacturing a semiconductor device according to an embodiment of the present invention.

FIG. 9 is a schematic cross-sectional view showing a method of manufacturing a semiconductor device according to an embodiment of the present invention.

FIG. 10 is a schematic cross-sectional view showing a method of manufacturing a semiconductor device according to an embodiment of the present invention.

FIG. 11 is a schematic cross-sectional view showing a method of manufacturing a semiconductor device according to an embodiment of the present invention.

FIG. 12 is a schematic cross-sectional view showing a method of manufacturing a semiconductor device according to an embodiment of the present invention.

FIG. 13 is a graph showing a correlation between a boron concentration and a sheet resistance of surfaces of a source and a drain region in Example Samples and Comparative Example Samples.

FIG. 14 is a schematic cross-sectional view illustrating a hydrogen trap region that traps hydrogen supplied from a protective insulating layer.

FIG. 15A is a graph showing the electrical characteristics of Example Samples 1-1.

FIG. 15B is a graph showing the electrical characteristics of Example Samples 1-2.

FIG. 15C is a graph showing the electrical characteristics of Example Samples 1-3.

FIG. 15D is a graph showing the electrical characteristics of Example Samples 1-4.

FIG. 16A is a graph showing the electrical characteristics of Example Samples 2-1.

FIG. 16B is a graph showing the electrical characteristics of Example Samples 2-2.

FIG. 16C is a graph showing the electrical characteristics of Example Samples 2-3.

FIG. 16D is a graph showing the electrical characteristics of Example Samples 2-4.

### DESCRIPTION OF EMBODIMENTS

In oxide semiconductors, carriers are generated when hydrogen is trapped in oxygen deficiencies. When this mechanism is utilized in a semiconductor device including an oxide semiconductor layer, that is, when oxygen deficiencies are formed in the oxide semiconductor layer and hydrogen is supplied to the formed oxygen deficiencies, a source region and a drain region with greater carrier concentration than a channel region can be formed in the oxide semiconductor layer. Silicon nitride contains a lot of hydrogen. Therefore, when a silicon nitride film is formed as a protective insulating layer of the semiconductor device and hydrogen contained in the silicon nitride film is supplied to the oxide semiconductor layer, the source region and the drain region that have low resistances can be formed. In other words, it is necessary to form the protective insulating layer including silicon nitride in order to lower the resistances of the source region and the drain region.

One object of an embodiment of the present invention is to provide a semiconductor device including a source region and a drain region with reduced resistances without depending on silicon nitride included in a protective insulating layer.

Each embodiment of the present invention is described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In the specification, a direction from a substrate to an oxide semiconductor layer is referred to as “on” or “over”. Reversely, a direction from the oxide semiconductor layer to the substrate is referred to as “under” or “below”. As described above, for convenience of explanation, although the phrase “over (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Over or below means a stacking order in a structure in which multiple layers are stacked, and when it is expressed as a pixel electrode above a semiconductor device, it may be a positional relationship where the semiconductor device and the pixel electrode do not overlap each other in a plan view. On the other hand, when it is expressed as a pixel electrode vertically above a semiconductor device, it means a positional relationship where the semiconductor device and the pixel electrode overlap each other in a plan view.

In the specification, the terms “film” and “layer” may be interchangeably used.

In the specification, “display device” refer to a structure configured to display an image using an electro-optic layer. For example, the term display device may refer to a display panel including the electro-optic layer, or it may refer to a structure in which other optical members (e.g., a polarizing member, a backlight, or a touch panel, etc.) are attached to a display cell. The “electro-optical layer” may include a liquid crystal layer, an electroluminescent (EL) layer, an electrochromic (EC) layer, or an electrophoretic layer as long as there is no technical contradiction. Therefore, although examples of a liquid crystal display device including a liquid crystal layer and an organic EL display device including an organic EL layer are described as the display device in the following embodiments, the structure of the present embodiment may be applied to the above display device including any electro-optic layer.

The expressions “a includes A, B, or C”, “a includes any of A, B, and C”, and “a includes one selected from a group consisting of A, B, and C” do not exclude the case where a includes multiple combinations of A to C unless otherwise specified. Furthermore, these expressions do not exclude the case where a includes other components.

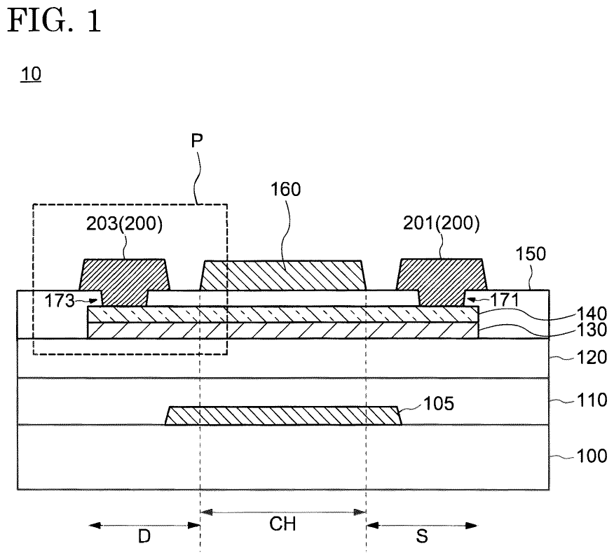

A semiconductor device 10 according to an embodiment of the present invention is described with reference to FIGS. 1 to 12. The semiconductor device 10 can be used in, for example, a display device, an integrated circuit (IC) such as a micro-processing unit (MPU), or a memory circuit.

### [1. Configuration of Semiconductor Device 10]

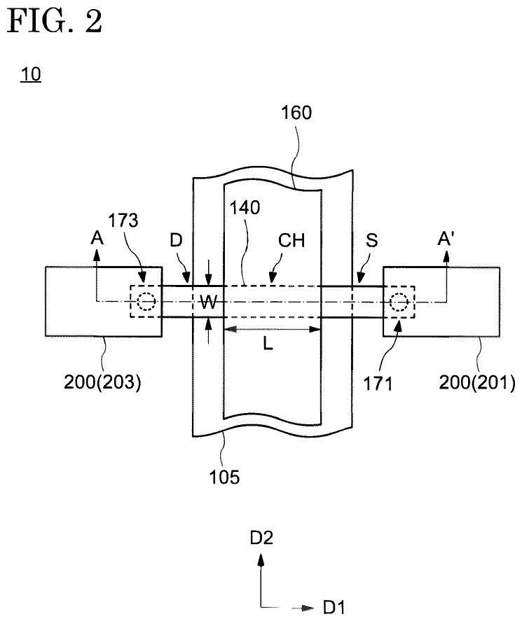

A configuration of the semiconductor device 10 according to an embodiment of the present invention is described with reference to FIGS. 1 and 2. FIG. 1 is a schematic cross-sectional view showing a configuration of the semiconductor device 10 according to an embodiment of the present invention. FIG. 2 is a schematic plan view showing a configuration of a semiconductor device 10 according to an embodiment of the present invention. Specifically, FIG. 1 is a cross-sectional view cut along a line A-A′ in FIG. 2.

As shown in FIG. 1, the semiconductor device 10 includes a substrate 100, a light shielding layer 105, a nitride insulating layer 110, a first oxide insulating layer 120, a second oxide insulating layer 130, an oxide semiconductor layer 140, a gate insulating layer 150, a gate electrode 160, a source electrode 201, and a drain electrode 203. The light shielding layer 105 is provided on the substrate 100. The nitride insulating layer 110 covers an upper surface and an end surface of the light shielding layer 105 and is provided on the substrate 100. The first oxide insulating layer 120 is provided on the nitride insulating layer 110. The second oxide insulating layer 130 has a predetermined pattern and is provided on the first oxide insulating layer 120. The oxide semiconductor layer 140 has a similar pattern to the second oxide insulating layer 130 and is provided on the second oxide insulating layer 130. The gate insulating layer 150 covers an upper surface of the oxide semiconductor layer 140 and an end surface of each of the second oxide insulating layer 130 and the oxide semiconductor layer 140, and is provided on the first oxide insulating layer 120. The gate electrode 160 overlaps the oxide semiconductor layer 140 and is provided on the gate insulating layer 150. The gate insulating layer 150 is provided with openings 171 and 173 through which parts of the upper surface of the oxide semiconductor layer 140 are exposed. The source electrode 201 is provided on the gate insulating layer 150 and inside the opening 171, and is in contact with the oxide semiconductor layer 140. Similarly, the drain electrode 203 is provided on the gate insulating layer 150 and inside the opening 173, and is in contact with the oxide semiconductor layer 140. The source electrode 201 and the drain electrode 203 are in contact with a surface of the gate insulating layer 150 which is in contact with the gate electrode 160. In addition, hereinafter, when the source electrode 201 and the drain electrode 203 are not particularly distinguished, they may be collectively referred to as a source/drain electrode 200.

The oxide semiconductor layer 140 is divided into a source region S, a drain region D, and a channel region CH based on the gate electrode 160. That is, the oxide semiconductor layer 140 includes the channel region CH which overlaps the gate electrode 160 and the source region S and the drain region D which do not overlap the gate electrode 160. In the thickness direction of the oxide semiconductor layer 140, an edge portion of the channel region CH substantially coincides with an edge portion of the gate electrode 160. The channel region CH has properties of a semiconductor. Each of the source region S and the drain region D has properties of a conductor. Therefore, the electrical conductivities of the source region S and the drain region D are greater than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

As shown in FIG. 2, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which a current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the semiconductor device 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH. For example, aluminum (Al), copper (Cu), titanium (Ti), molybdenum (Mo), tungsten (W), or alloys or compounds thereof can be used for the light shielding layer 105. Further, the light shielding layer 105 may not necessarily include a metal when conductivity of the light shielding layer 105 is not required. For example, a black matrix made of black resin can be used for the light shielding layer 105. Furthermore, the light shielding layer 105 may have a single layer structure or a laminated structure. For example, the light shielding layer 105 may have a laminated structure of a red color filter, a green color filter, and a blue color filter.

The nitride insulating layer 110 can prevent the diffusion of impurities (e.g., sodium etc.) contained in the substrate 100 or impurities (e.g., water etc.) entering from the outside into the oxide semiconductor layer 140. For example, a nitride containing silicon or aluminum can be used for the nitride insulating layer 110. Specifically, silicon nitride (SiNₓ), silicon nitride oxide (SiNₓO_{y}), aluminum nitride (AlNₓ), or aluminum nitride oxide (AlNₓO_{y}) and the like can be used for the nitride insulating layer 110. Further, the nitride insulating layer 110 may have a single layer structure or a laminated structure.

Each of the first oxide insulating layer 120, the second oxide insulating layer 130, and the gate insulating layer 150 can suppress diffusion of hydrogen into the channel region CH. In particular, when a hydrogen trap region, which is described later, is formed in at least one of the first oxide insulating layer 120, the second oxide insulating layer 130, or the gate insulating layer 150, the effect of suppressing the diffusion of hydrogen is high. For example, an oxide containing silicon or aluminum can be used for each of the first oxide insulating layer 120, the second oxide insulating layer 130, and the gate insulating layer 150. Specifically, silicon nitride (SiNₓ), silicon nitride oxide (SiNₓO_{y}), aluminum nitride (AlNₓ), or aluminum nitride oxide (AlNₓO_{y}) and the like can be used for each of the first oxide insulating layer 120, the second oxide insulating layer 130, and the gate insulating layer 150. The oxide included in the second oxide insulating layer 130 is different from the oxide included in the first oxide insulating layer 120. Since the predetermined pattern of the second oxide insulating layer 130 is formed by etching, it is preferable that the first oxide insulating layer 120 and the second oxide insulating layer 130 be made of oxides with different etching rates. It is preferable to use aluminum oxide for the second oxide insulating layer 130. Each of the first oxide insulating layer 120, the second oxide insulating layer 130, and the gate insulating layer 150 may have a single layer structure or a laminated structure.

In addition, in the embodiment, it is also possible to apply a configuration in which the second oxide insulating layer 130 is not provided.

Here, silicon oxynitride (SiOₓN_{y}) and aluminum oxynitride (AlOₓ N_{y}) are oxides that contain a smaller proportion (x>y) of nitrogen (N) than oxygen (O). Silicon nitride oxide (SiNₓO_{y}) and aluminum nitride oxide (AlNₓO_{y}) are nitrides that contain a smaller proportion (x>y) of oxygen than nitrogen.

The gate electrode 160, the source electrode 201, and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the gate electrode 160, the source electrode 201, and the drain electrode 203. Each of the gate electrode 160, source electrode 201, and drain electrode 203 may have a single layer structure or a laminated structure.

An oxide semiconductor containing two or more metal elements including indium (In), gallium (Ga), zinc (Zn), aluminum (Al), hafnium (Hf), yttrium (Y), zirconium (Zr), and lanthanoids are used for the oxide semiconductor layer 140. The oxide semiconductor layer 140 may have an amorphous structure or a polycrystalline structure. However, the oxide semiconductor layer 140 preferably has a polycrystalline structure in order to improve electrical characteristics. In particular, the crystal structures of the source region S and the drain region D are preferably the same as the crystal structure of the channel region CH.

When the oxide semiconductor layer 140 has a polycrystalline structure, it is preferable that an oxide semiconductor in which the atomic ratio of indium to all metal elements is greater than or equal to 50% is used for the oxide semiconductor layer 140. When the ratio of the indium is increased, the oxide semiconductor layer 140 is easily crystallized. Further, it is preferable that gallium is contained as a metal element other than indium. Gallium belongs to the same group 13 elements as indium. Therefore, the oxide semiconductor layer 140 has a polycrystalline structure without gallium inhibiting the crystallinity of the oxide semiconductor layer 140.

Although a detailed method for manufacturing the oxide semiconductor layer 140 is described in a method for manufacturing the semiconductor device, which is described later, the oxide semiconductor layer 140 can be formed using a sputtering method. The composition of the oxide semiconductor layer 140 formed by sputtering depends on the composition of the sputtering target. When the oxide semiconductor layer 140 has a polycrystalline structure, the composition of the oxide semiconductor layer 140 is substantially identical to the composition of the sputtering target. In this case, the composition of the metal elements in the oxide semiconductor layer 140 can be specified based on the composition of the metal elements in the sputtering target. Further, when the oxide semiconductor layer 140 has a polycrystalline structure, the composition of the oxide semiconductor layer 140 may be specified by an X-ray diffraction (XRD) method. Specifically, the composition of the metal elements in the oxide semiconductor layer 140 can be specified based on the crystal structure and lattice constant of the oxide semiconductor layer 140 obtained by the XRD method. Furthermore, the composition of the metal elements of the oxide semiconductor layer 140 can also be identified using fluorescent X-ray analysis, electron probe microanalyzer (EPMA) analysis, or the like. In addition, oxygen contained in the oxide semiconductor layer 140 is not limited to this because oxygen changes depending on the sputtering process conditions and the like.

As described above, the oxide semiconductor layer 140 may have an amorphous structure or a polycrystalline structure. An oxide semiconductor having a polycrystalline structure can be manufactured using a poly-crystalline oxide semiconductor (Poly-OS) technology. Hereinafter, the oxide semiconductor having a polycrystalline structure may be described as Poly-OS when distinguished from an oxide semiconductor having an amorphous structure.

### [2. Configuration of Hydrogen Trap Region]

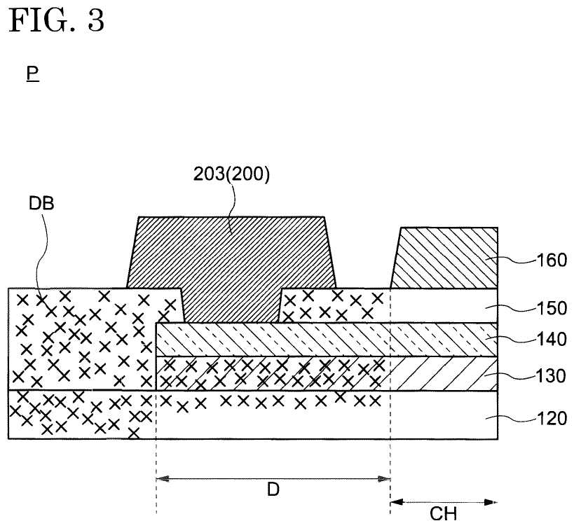

FIG. 3 is a schematic partially enlarged sectional view showing a configuration of the semiconductor device 10 according to an embodiment of the present invention. Specifically, FIG. 3 is an enlarged cross-sectional view of a region P in FIG. 1. In addition, although the region P shown in FIG. 3 is a region near the drain region D, a region near the source region S also has the same configuration as the region P.

Although details are described later, the source region S and the drain region D of the oxide semiconductor layer 140 are formed by ion implantation of an impurity using the gate electrode 160 as a mask. For example, boron (B), phosphorus (P), argon (Ar), nitrogen (N), or the like is used as the impurity. Oxygen deficiencies are formed in the source region S and drain region D of the oxide semiconductor layer 140 by the ion implantation. Then, when hydrogen is trapped in the formed oxygen deficiencies, the resistances of the source region S and the drain region D are reduced.

The ion implantation is performed through the gate insulating layer 150. At this time, dangling bond defects DB (marked with an x in FIG. 3) are formed in the gate insulating layer 150 by the ion implantation. Further, in the ion implantation, the impurities are distributed in the depth direction, and the impurities are implanted not only into the gate insulating layer 150 but also into the first oxide insulating layer 120 and the second oxide insulating layer 130. Therefore, the dangling bond defects DB are also formed in the first oxide insulating layer 120 and the second oxide insulating layer 130. In addition, as described above, since the ion implantation of the impurity is performed using the gate electrode 160 as a mask, no impurity is implanted into the region overlapping the gate electrode 160, and no dangling bond defect DB is formed.

When the amount of the dangling bond defects DB in a certain region exceeds a predetermined value, that region functions as a hydrogen trap region that traps hydrogen. That is, when the dangling bond defects DB exceeding a predetermined amount of defects are formed in the gate insulating layer 150, the hydrogen trap region is formed in the gate insulating layer 150. Since the hydrogen trap region is formed by the ion implantation, the hydrogen region does not overlap the gate electrode 160. Although details are described later, at the interface between the gate insulating layer 150 and the oxide semiconductor layer 140 (specifically, the source region S and drain region D of the semiconductor layer 140), the impurity concentration of the surfaces of the source region S and drain region D is greater than or equal to 2×10¹⁷ cm⁻³, and the hydrogen trap region is formed in the gate insulating layer 150. In addition, it is preferable that the impurity concentration of the surfaces of the source region S and drain region D is greater than or equal to 2×10¹⁹ cm⁻³ in order to obtain good electrical characteristics for the semiconductor device 10.

Here, “impurity concentration of at the surface” refers to the concentration of impurities near the surface. Further, “near the surface” refers to a region included from the interface between the gate insulating layer 150 and the oxide semiconductor layer 140 (or the upper surface of the oxide semiconductor layer 140) to a depth of 4 nm in the thickness direction of the oxide semiconductor layer 140. However, the depth near the surface is not limited to 4 nm. For example, the depth near the surface may be ⅕ of the thickness of the oxide semiconductor layer 140, based on the thickness of the oxide semiconductor layer 140. Further, the impurity concentration may be a value converted from the dose amount of the ion implantation, or may be a value measured by analysis such as secondary ion mass spectroscopy (SIMS).

As described above, the dangling bond defects DB are formed not only in the gate insulating layer 150 but also in the first oxide insulating layer 120 and the second oxide insulating layer 130. Therefore, a hydrogen trap region that does not overlap the gate electrode 160 may also be formed in the first oxide insulating layer 120 and the second oxide insulating layer 130. The hydrogen trap region of each of the first oxide insulating layer 120, the second oxide insulating layer 130, and the gate insulating layer can significantly suppress hydrogen diffusion into the channel region CH.

When silicon oxide is used for the first oxide insulating layer 120, silicon dangling bond defects DB are formed in the first oxide insulating layer 120. When aluminum oxide is used for the second oxide insulating layer 130, aluminum dangling bond defects DB are formed in the second oxide insulating layer 130. In this way, different types of dangling bond defects DB can be formed in the first oxide insulating layer 120 and the second oxide insulating layer 130 to differentiate the hydrogen trapping performance in the hydrogen trapping region.

In addition, since hydrogen is trapped in the hydrogen trap region, the hydrogen trap region that does not overlap the gate electrode 160 has a higher concentration of hydrogen than the region that overlaps the gate electrode 160.

The configuration of the semiconductor device 10 is described above, and the semiconductor device 10 described above is a so-called top-gate transistor. Various modifications can be applied to the semiconductor device 10. For example, when the light shielding layer 105 has conductivity, the semiconductor device 10 may have a configuration in which the light shielding layer 105 functions as a gate electrode, and the nitride insulating layer 110, the first oxide insulating layer 120, and the second oxide insulating layer 130 function as gate insulating layers. In this case, the semiconductor device 10 is a so-called dual-gate transistor. Further, when the light shielding layer 105 has conductivity, the light shielding layer 105 may be a floating electrode and may be connected to the source electrode 201. Furthermore, the semiconductor device 10 may be a so-called bottom-gate transistor in which the light shielding layer 105 functions as a main gate electrode.

### [3. Manufacturing Method of Semiconductor Device 10]

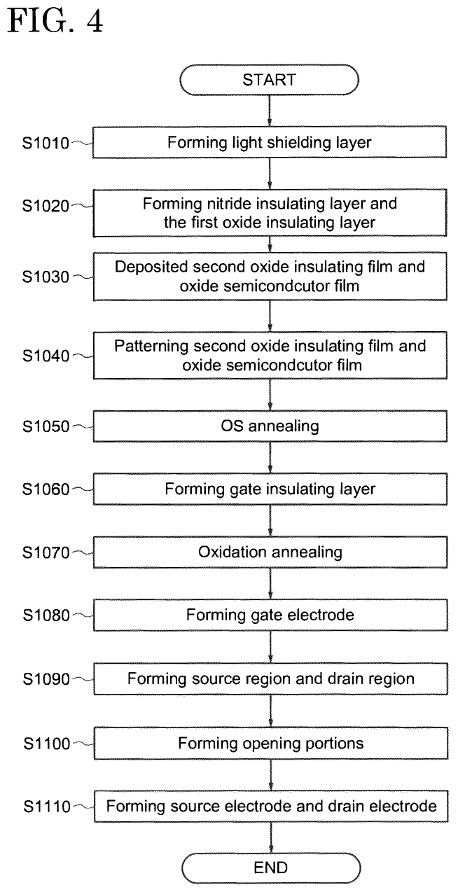

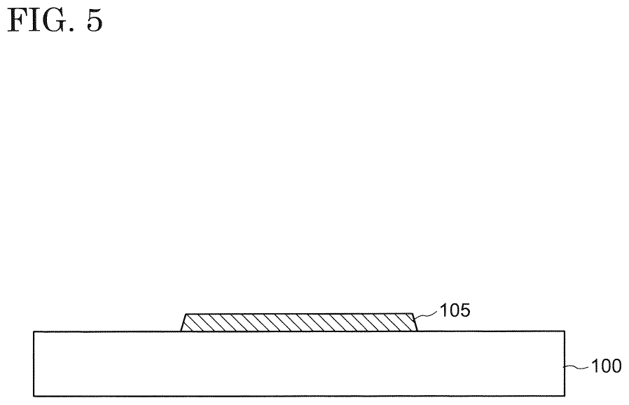

A method for manufacturing the semiconductor device 10 according to an embodiment of the present invention is described with reference to FIGS. 4 to 12. FIG. 4 is a flow chart showing a method of manufacturing the semiconductor device 10 according to an embodiment of the present invention. FIGS. 5 to 12 are schematic cross-sectional views showing a method of manufacturing the semiconductor device 10 according to an embodiment of the present invention.

As shown in FIG. 4, the method for manufacturing the semiconductor device 10 includes steps S1010 to S1110. In the following description, although steps S1010 to S1110 are described in order, the order of the steps may be interchanged in the method for manufacturing the semiconductor device 10. Further, the method for manufacturing the semiconductor device 10 may include additional steps.

In step S1010, the light shielding layer 105 having a predetermined pattern is formed on the substrate 100 (see FIG. 5). The patterning of the light shielding layer 105 is performed using a photolithographic method.

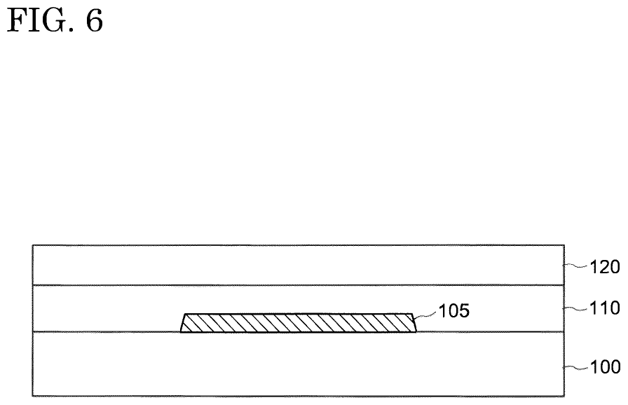

In step S1020, the nitride insulating layer 110 and the first oxide insulating layer 120 are sequentially formed on the light shielding layer 105 (see FIG. 6). The nitride insulating layer 110 and the first oxide insulating layer 120 are deposited using a CVD method. For example, a silicon nitride film and a silicon oxide film are deposited as the nitride insulating layer 110 and the first oxide insulating layer 120, respectively. The silicon nitride film and the silicon oxide film can also be formed continuously in the same chamber by changing the reactive gas.

In a step described later, dangling bond defects having a hydrogen trapping function are formed in a predetermined region of the first oxide insulating layer 120. Therefore, the first oxide insulating layer 120 does not have to be a film containing excess oxygen that traps hydrogen, and is preferably a dense film with few defects that is formed at a temperature higher than or equal to 350° C. When the first oxide insulating layer 120 is a film containing excess oxygen, the reliability of the semiconductor device 10 is reduced. On the other hand, the reliability of the semiconductor device 10 can be improved by forming the dense film as the first oxide insulating layer 120.

For example, the thickness of the nitride insulating layer 110 is greater than or equal to 50 nm and less than or equal to 500 nm, and preferably greater than or equal to 150 nm and less than or equal to 300 nm. Further, for example, the thickness of the oxide insulating layer 120 is greater than or equal to 50 nm and less than or equal to 500, and preferably greater than or equal to 150 nm and less than or equal to 300 nm.

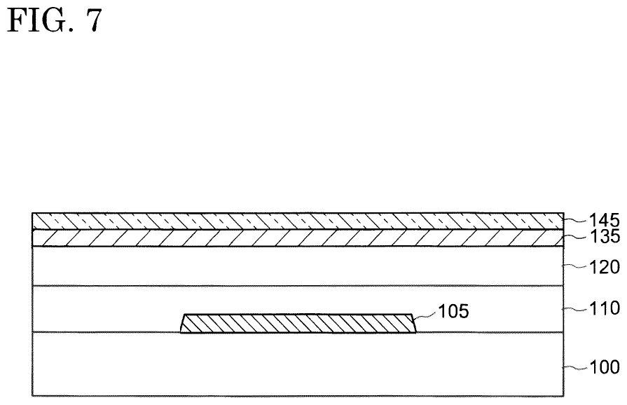

In step S1030, a second oxide insulating film 135 and an oxide semiconductor film 145 are deposited on the first oxide insulating layer 120 (see FIG. 7). The second oxide insulating film 135 and the oxide semiconductor film 145 are deposited by a sputtering method. An aluminum oxide film is deposited as the second oxide insulating film. For example, the thickness of the second oxide insulating film 135 is greater than or equal to 1 nm and less than or equal to 30 nm, preferably greater than or equal to 1 nm and less than or equal to 20 nm, and more preferably greater than or equal to 1 nm and less than or equal to 10 nm. For example, the thickness of the oxide semiconductor film 145 is greater than or equal to 10 nm and less than or equal to 100 nm, preferably greater than or equal to 15 nm and less than or equal to 70 nm, and more preferably greater than or equal to 15 nm and less than or equal to 40 nm.

The oxide semiconductor film 145 in step S1030 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor layer 140 immediately after the deposition is not crystallized as much as possible. When the oxide semiconductor film 145 is formed by the sputtering method, the oxide semiconductor film 145 is deposited while controlling the temperature of the object to be deposited (the substrate 100 and the layers formed thereon) to less than or equal to 100° C., preferably less than or equal to 80° C., and preferably less than or equal to 50° C. Further, the oxide semiconductor film 145 is deposited under a condition of low oxygen partial pressure. The oxygen partial pressure is greater than or equal to 2% and less than or equal to 20%, preferably greater than or equal to 3% and less than or equal to 15%, and more preferably greater than or equal to 3% and less than or equal to 10%.

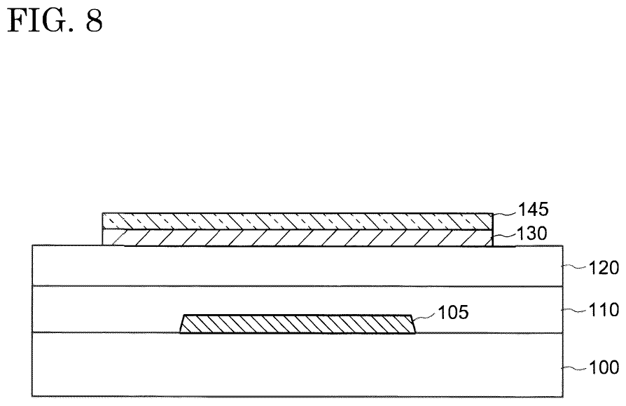

In step S1040, the second oxide insulating film 135 and the oxide semiconductor film 145 are patterned (see FIG. 8). The patterning of the second oxide insulating film 135 and the oxide semiconductor film 145 is performed using a photolithography method. Wet etching or dry etching may be used for the etching of the second oxide insulating film 135 and the oxide semiconductor film 145. The wet etching can be performed using an acidic etchant. For example, oxalic acid, PAN, sulfuric acid, hydrogen peroxide solution, hydrofluoric acid, or the like can be used for the etchant. Since the oxide semiconductor film 145 in step S1040 is amorphous, the oxide semiconductor film 145 can be easily patterned into a predetermined shape by wet etching. Further, the second oxide insulating film 135 can also be patterned into a predetermined shape using the oxide semiconductor film 145 as a mask. As a result, the second oxide insulating layer 130 is formed.

In step S1050, a heat treatment is performed on the oxide semiconductor film 145. Hereinafter, the heat treatment performed in step S1050 is referred to as “OS annealing”. In the OS annealing, the oxide semiconductor film 145 is held at a predetermined reaching temperature for a predetermined time. The predetermined reaching temperature is higher than or equal to 300° C. and lower than or equal to 500° C., and preferably higher than or equal to 350° C. and lower than or equal to 450° C. Further, the holding time at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure (that is, the oxide semiconductor layer 140 including a Poly-OS) by the OS annealing.

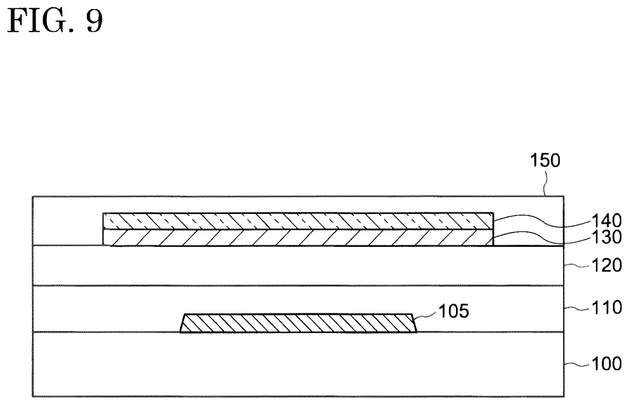

In step S1060, the gate insulating layer 150 is deposited on the second oxide insulating layer 130 and the oxide semiconductor layer 140 (see FIG. 9). The gate insulating layer 150 is deposited using the CVD method. For example, silicon oxide is deposited for the gate insulating layer 150. In order to reduce defects in the gate insulating layer 150, the gate insulating layer 150 may be deposited at a deposition temperature higher than or equal to 350° C. The thickness of the gate insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm.

In step S1070, a heat treatment is performed on the oxide semiconductor layer 140. Hereinafter, the heat treatment performed in step S1070 is referred to as “oxidation annealing”. When the gate insulating layer 150 is formed on the oxide semiconductor layer 140, many oxygen deficiencies are generated on the upper surface and side surfaces of the oxide semiconductor layer 140. When oxidation annealing is performed, oxygen is supplied to the oxide semiconductor layer 140 through the second oxide insulating layer 130 and the gate insulating layer 150, and the oxygen deficiencies in the oxide semiconductor layer 140 are repaired.

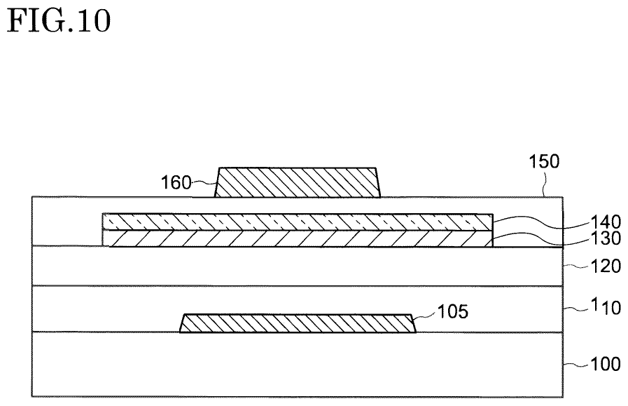

In step S1080, the gate electrode 160 having a predetermined pattern is formed on the gate insulating layer 150 (see FIG. 10). The gate electrode 160 is deposited by the sputtering method or an atomic layer deposition method, and patterning of the gate electrode 160 is performed using the photolithographic method.

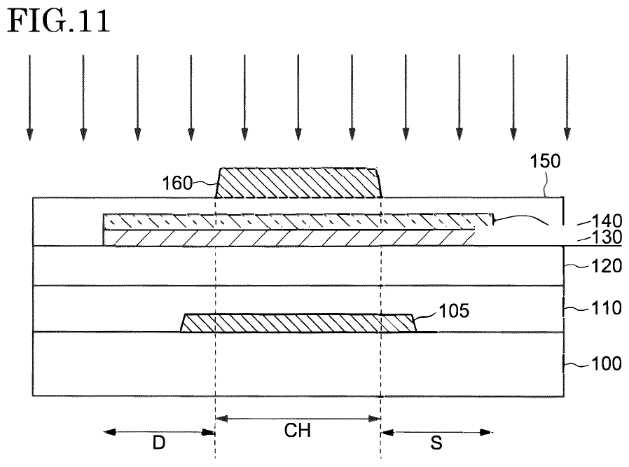

In step S1090, the source region S and the drain region D are formed in the oxide semiconductor layer 140 (see FIG. 11). The source region S and the drain region D are formed by ion implantation. The ion implantation can be performed using an ion doping device or an ion implantation device. Specifically, an impurity is implanted into the oxide semiconductor layer 140 through the gate insulating layer 150 using the gate electrode 160 as a mask. For example, boron (B), phosphorus (P), argon (Ar), nitrogen (N), or the like is used as the implanted impurity. Oxygen vacancies are generated by the ion implantation in the source region S and the drain region D that do not overlap the gate electrode 160, so that hydrogen is trapped in the generated oxygen vacancies. Thereby, the resistance of the source region S and the drain region D is lowered. On the other hand, in the channel region CH that overlaps the gate electrode 160, an impurity is not implanted, so that oxygen vacancies are not generated and the resistance of the channel region CH does not decrease.

Further, in step S1090, the impurity is also implanted into the gate insulating layer 150, the second oxide insulating layer 130, and the first oxide insulating layer 120. The dangling bond defects DB are generated in the gate insulating layer 150, the second oxide insulating layer 130, and the first oxide insulating layer 120 by the ion implantation. That is, the hydrogen trap region due to the dangling bond defects DB is formed in each of the gate insulating layer 150, the second oxide insulating layer 130, and the first oxide insulating layer 120. Since the hydrogen trap region is formed by the ion implantation, the hydrogen trap region contains the impurity such as boron (B), phosphorus (P), argon (Ar), or nitrogen (N).

In the ion implantation in step S1090, at the interface between the gate insulating layer 150 and the oxide semiconductor layer 140 (specifically, the source region S and drain region D of the oxide semiconductor layer 140), the impurity concentration of the surfaces of the source region S and drain region D is reduced. The ion implantation process parameters (e.g., dose amount, acceleration voltage, plasma power, etc.) are controlled so that the ion implantation density is greater than or equal to 1×10¹⁹ cm⁻³. For example, although the dose amount is greater than or equal to 1×10¹⁴ cm⁻², and the acceleration voltage is greater than or equal to 20 keV, the process parameters are not limited thereto.

When the impurity concentration of the surface of the oxide semiconductor layer 140 is greater than or equal to 1×10¹⁹ cm⁻³, sufficient oxygen deficiencies are formed in the source region S and the drain region D. Further, the dangling bond defects DB are formed in the first oxide insulating layer 120, the second oxide insulating layer 130, and the gate insulating layer 150, and hydrogen is generated. In this case, even when a protective insulating layer including silicon nitride is not provided on the gate insulating layer 150, hydrogen generated in the first oxide insulating layer 120, the second oxide insulating layer 130, and the gate insulating layer 150 is supplied to the oxygen deficiencies formed in the source region S and the drain region D. Therefore, the resistances of the source region S and drain region D are sufficiently reduced.

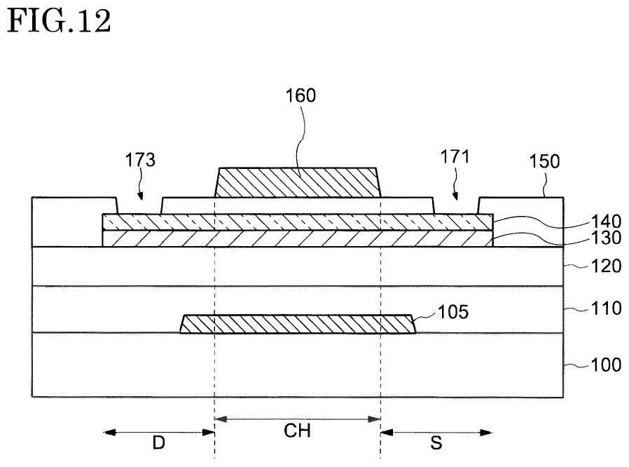

In step S1100, the opening portions 171 and 173 are formed in the gate insulating layer 150 (see FIG. 12). The source region S and the drain region D of the oxide semiconductor layer 140 are exposed by forming the opening portions 171 and 173.

In step S1110, the source electrode 201 is formed on the gate insulating layer 170 and inside the opening 171, and the drain electrode 203 is formed on the gate insulating layer 170 and inside the opening 173. The source electrode 201 and the drain electrode 203 are formed as the same layer. Specifically, the source electrode 201 and the drain electrode 203 are formed by patterning one deposited conductive film. Through the above steps, the semiconductor device 10 shown in FIG. 1 is manufactured.

The method for manufacturing the semiconductor device 10 is not limited to the steps described above. For example, a step of forming a protective insulating layer may be included after step S1110. In the embodiment, since the resistances of the source region S and the drain region D are sufficiently reduced in step S1090, a configuration in which the protective insulating layer does not include silicon nitride is also possible. For example, a planarizing film such as polyimide resin or the like can be used as the protective insulating layer.

As described above, in the semiconductor device 10 according to the embodiment of the present invention, the hydrogen trap region is formed in the gate insulating layer 150, and the oxygen defects are formed in the source region S and the drain region D. Further, hydrogen is generated in the first oxide insulating layer 120, the second oxide insulating layer 130, and the gate insulating layer 150 due to the ion implantation. When the impurity concentration of the surfaces of the source region S and the drain region D is greater than or equal to 1×10¹⁹ cm⁻³, sufficient oxygen defects are formed in the source region S and the drain region D. In this case, hydrogen generated in the first oxide insulating layer 120, the second oxide insulating layer 130, and the gate insulating layer 150 is supplied to the oxygen defects formed in the source region S and the drain region D. Therefore, the semiconductor device 10 includes the source region S and the drain region D with low resistance, and has electrical characteristics in which depletion is suppressed, regardless of whether a protective insulating layer including silicon nitride is formed.

### EXAMPLE

The semiconductor device 10 is described in more detail based on the manufactured sample.

### [1. Manufacture of Example Sample]

As Example 1, four semiconductor devices (Example Samples 1-1 to 1-4) in which the impurity (boron) concentration of the surfaces of the source region and the drain region was greater than or equal to 1×10¹⁹ cm⁻³ were manufactured using the above-described manufacturing method during control of the accelerating voltage and the dose amount. Further, as Example 2, four semiconductor devices (Example Samples 2-1 to 2-4) in which the protective insulating layer including silicon nitride was provided and the impurity (boron) concentration of the surfaces of the source region and the drain region was greater than or equal to 1×10¹⁹ cm⁻³ were manufactured. Specifically, in Example 2, the protective insulating layer including silicon nitride was formed after step S1090. Thereafter, similar to steps S1100 and S1110, openings were formed in the protective insulating layer and the gate insulating layer, and the source electrode and the drain electrode were formed through the openings so as to be electrically connected to the source region and the drain region, respectively.

### [2. Manufacture of Comparative Example Sample]

As Comparative Example 1, nine semiconductor devices (Comparative Example Samples 1-1 to 1-9) in which the impurity (boron) concentration of the surfaces of the source region and the drain region was less than 1×10¹⁹ cm⁻³ were manufactured using the same manufacturing method as in Example 1, during control of the acceleration voltage and the dose amount. Further, as Comparative Example 2, nine semiconductor devices (Comparative Example Samples 2-1 to 2-9) in which the protective insulating layer including silicon nitride was provided and the impurity (boron) concentration of the surfaces of the source region and the drain region was less than 1×10¹⁹ cm⁻³ were manufactured using the same manufacturing method as in Example 2.

In addition, in any of the Example Samples and the Comparative Example Samples, the oxide semiconductor layer contained indium, and the atomic ratio of indium to all metal elements was greater than or equal to 50%. Further, although the oxide semiconductor layer had an amorphous structure before the OS annealing, the oxide semiconductor layer had a polycrystalline structure when the oxide semiconductor layer was crystallized by the OS annealing. That is, all of the oxide semiconductor layers of the Example Sample and the Comparative Example Sample included Poly-OS.

Table 1 shows the boron concentrations of the surfaces of the source region and the drain region in the Example Samples. Further, table 2 shows the boron concentrations of the surfaces of the source region and the drain region in the Comparative Example Samples. The boron concentration was calculated from the dose amount in the ion implantation.

TABLE 1

| | Boron |
|---|---|
| | Concentration |
| Sample Name | (cm⁻³) |
| Example Sample 1-1 | 1.1 × 10¹⁹ |
| Example Sample 1-2 | 1.4 × 10¹⁹ |
| Example Sample 1-3 | 1.1 × 10²⁰ |
| Example Sample 1-4 | 1.4 × 10²⁰ |
| Example sample 2-1 | 1.1 × 10¹⁹ |
| Example sample 2-2 | 1.4 × 10¹⁹ |
| Example sample 2-3 | 1.1 × 10²⁰ |
| Example sample 2-4 | 1.4 × 10²⁰ |

TABLE 2

| | Boron |
|---|---|
| | concentration |
| Sample Name | (cm⁻³) |
| Comparative Example Sample 1-1 | 0 |
| Comparative Example Sample 1-2 | 9.0 × 10¹⁵ |
| Comparative Example Sample 1-3 | 9.0 × 10¹⁵ |
| Comparative Example Sample 1-4 | 9.0 × 10¹⁵ |
| Comparative Example Sample 1-5 | 9.0 × 10¹⁵ |
| Comparative Example Sample 1-6 | 3.3 × 10¹⁶ |
| Comparative Example Sample 1-7 | 3.3 × 10¹⁷ |
| Comparative Example Sample 1-8 | 1.1 × 10¹⁸ |
| Comparative Example Sample 1-9 | 1.4 × 10¹⁸ |
| Comparative Example Sample 2-1 | 0 |
| Comparative Example Sample 2-2 | 9.0 × 10¹⁵ |
| Comparative Example sample 2-3 | 9.0 × 10¹⁵ |
| Comparative Example Sample 2-4 | 9.0 × 10¹⁵ |
| Comparative Example Sample 2-5 | 9.0 × 10¹⁵ |
| Comparative Example Sample 2-6 | 3.3 × 10¹⁶ |
| Comparative Example Sample 2-7 | 3.3 × 10¹⁷ |
| Comparative Example Sample 2-8 | 1.1 × 10¹⁸ |
| Comparative Example Sample 2-9 | 1.4 × 10¹⁸ |

### [3. Measurement of Sheet Resistance]

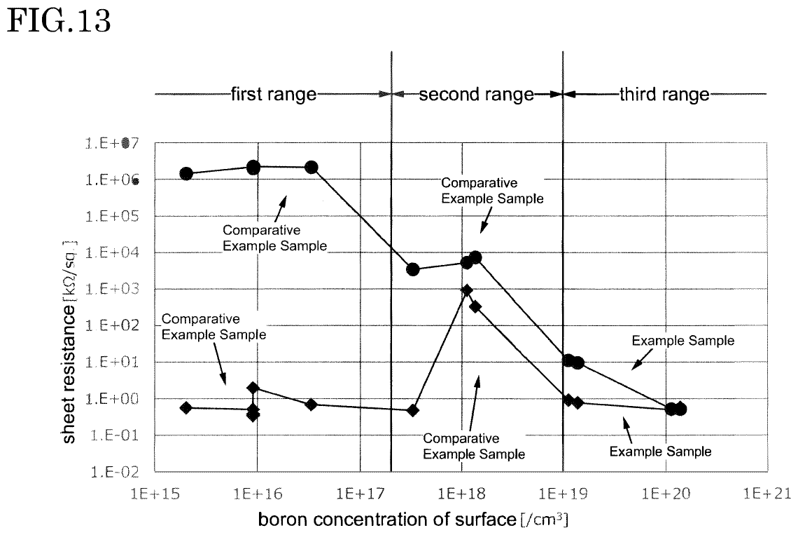

FIG. 13 is a graph showing the correlation between the boron concentration and the sheet resistance of the surfaces of the source region and the drain region in the Example Samples and the Comparative Example Samples. In the graph of FIG. 13, for convenience of explanation, the boron concentrations of the Comparative Example Samples 1-1 and 2-1 are plotted as 2×10¹⁵ cm⁻³.

The graph shown in FIG. 13 is divided into three ranges based on the boron concentration of the surfaces of the source region and the drain region. The first range is less than 2×10¹⁷ cm⁻³, the second range is greater than or equal to 2×10¹⁷ cm⁻³ and less than 1×10¹⁹ cm⁻³, and the third range is greater than or equal to 1×10¹⁹ cm⁻³. The Comparative Example Samples 1-1 to 1-6 and the Comparative Example Samples 2-1 to 2-6 belong to the first range. The Comparative Example Samples 1-7 to 1-9 and the Comparative Example Samples 2-7 to 2-9 belong to the second range. The Example Samples 1-1 to 1-4 and the Example samples 2-1 to 2-4 belong to the third range.

In the first range, the sheet resistances of the source region and the drain region of the Comparative Example Samples 1-1 to 1-6 are greater than the sheet resistances of the source region and the drain region of the Comparative Example Samples 2-1 to 2-6. The Comparative Example Samples 2-1 to 2-6 are provided with the protective insulating layer including silicon nitride, so that sufficient hydrogen is supplied from the protective insulating layer to the source region and the drain region. Therefore, the resistances of the source region and the drain region of the Comparative Example Sample 2-1 to 2-5 are reduced. On the other hand, in the Comparative Example Samples 1-1 to 1-6, the protective insulating layer including silicon nitride is not provided. Therefore, hydrogen is not supplied to the source region and the drain region of the Comparative Example Samples 1-1 to 1-6, and the resistances of the source region and the drain region are not reduced.

The first range is a range where the resistances of the source region and the drain region are reduced by supplying hydrogen from the protective insulating layer including silicon nitride. However, in the first range, sufficient oxygen defects are not formed in the source region and the drain region. Therefore, hydrogen supplied to the source region and the drain region diffuses into the channel region without being trapped in the source region and the drain region. Therefore, in the first range, it is difficult to obtain electrical characteristics that indicate switching performance.

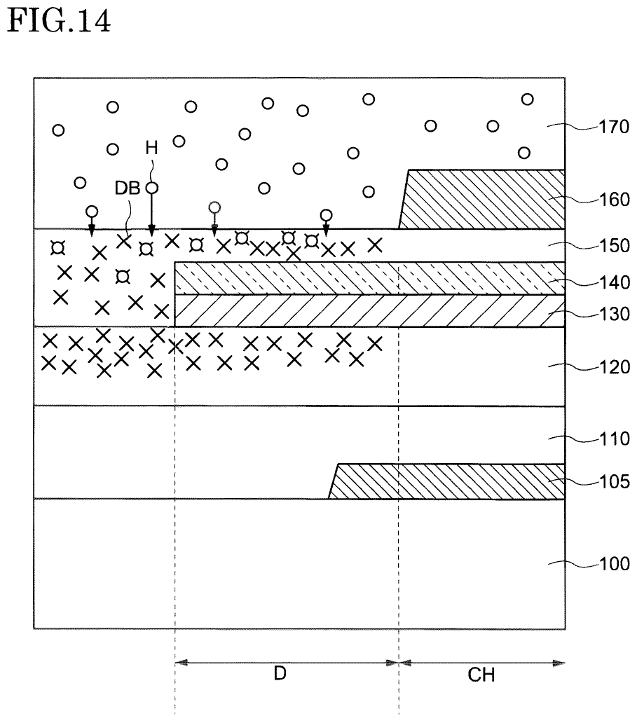

In the second range, as can be understood from the trends of the Comparative Example Samples 2-7 to 2-9, the sheet resistances of the source region and the drain regions increase. Similarly, in the Comparative Example Samples 1-7 to 1-9, although the sheet resistances of the source region and the drain region tend to decrease overall, the sheet resistances of the source region and the drain region increase. Here, the reason why the sheet resistances of the source region and the drain region increase is described with reference to FIG. 14.

FIG. 14 is a schematic cross-sectional view illustrating a hydrogen trap region that traps hydrogen supplied from the protective insulating layer 170.

As shown in FIG. 14, when sufficient dangling bond defects DB are formed in the gate insulating layer 150 to form the hydrogen trap region, hydrogen supplied from the protective insulating layer 170 including silicon nitride to the source region S and the drain region D is suppressed by the hydrogen trap region. Therefore, although the source region S and the drain region D have oxygen deficiencies, hydrogen is not supplied to the oxygen deficiencies, so the sheet resistances of the source region S and the drain region D increase.

The second range is a range where the hydrogen trap region is formed in the gate insulating layer by the ion implantation. In the second range, hydrogen is preferentially trapped in the hydrogen trap region, so that the supply of hydrogen to the source region and the drain region is suppressed. Therefore, in the second range, the contact resistances between the source region and the source electrode and between the drain region and the drain electrode become large, and the current flowing through the channel region is suppressed. As a result, electrical characteristics with reduced on-state current can be obtained.

In the third range, the sheet resistances of the source region and the drain region of the Example Samples 1-1 to 1-4 are less than or equal to 1×10² kΩ/sq which are approximately the same as the sheet resistances of the source region and the drain region of the Example Samples 2-1 to 2-4. That is, in the Example Samples 1-1 to 1-4, the resistances of the source region and the drain region are sufficiently reduced even without the supply of hydrogen from the protective insulating layer.

In the third range, since sufficient oxygen defects are formed in the source region and the drain region by the ion implantation, hydrogen is supplied from the first oxide insulating layer and the second oxide insulating layer to the oxygen deficiencies of the source region and the drain region. That is, since the amount of hydrogen supplied to the source region and the drain region is controlled according to the oxygen deficiencies, diffusion of hydrogen into the channel region is suppressed. Therefore, electrical characteristics that exhibit switching performance and suppress depletion can be obtained.

### [4. Measurement of Electrical Characteristics]

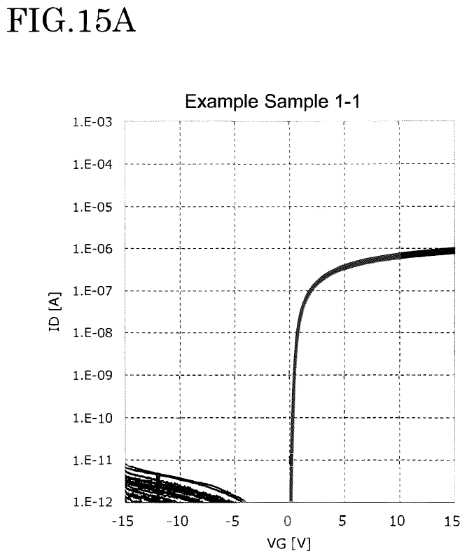

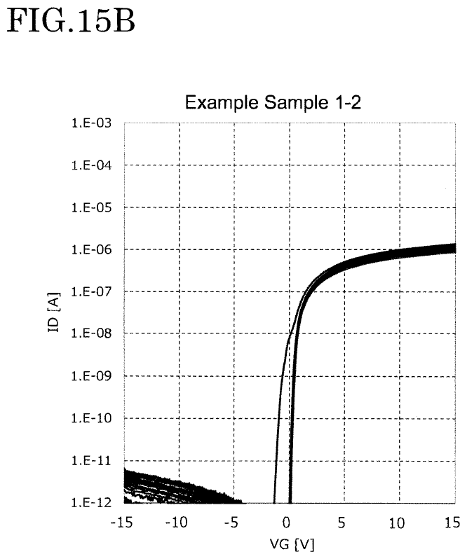

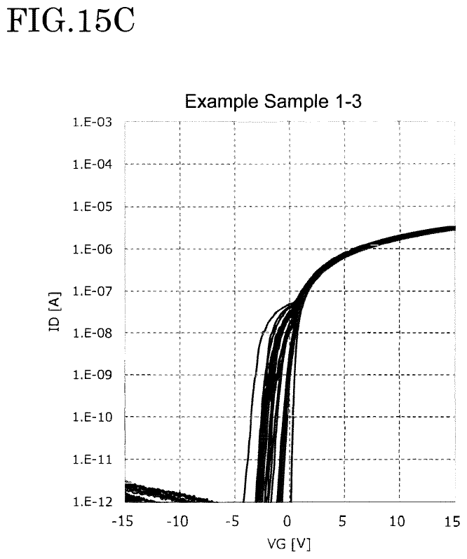

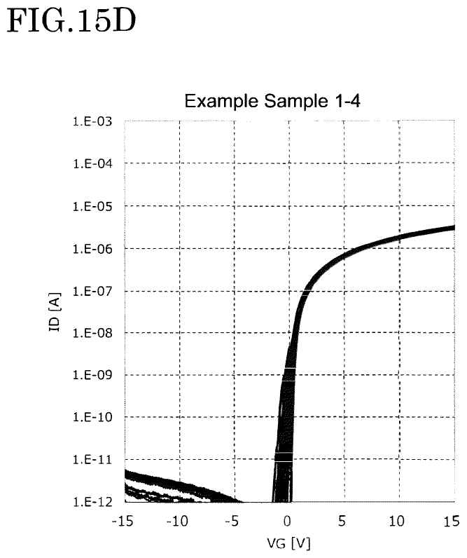

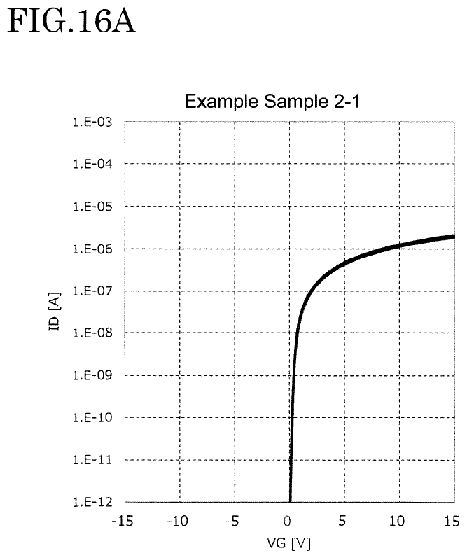

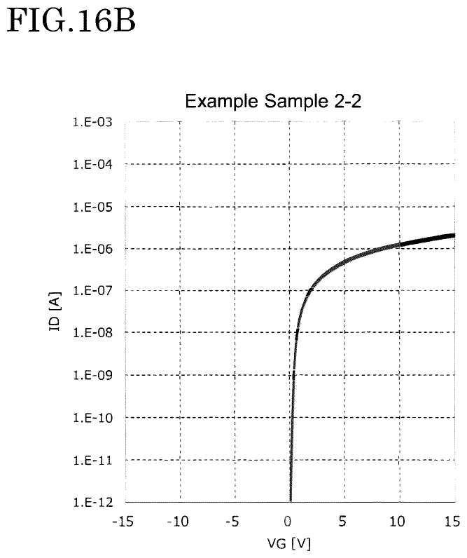

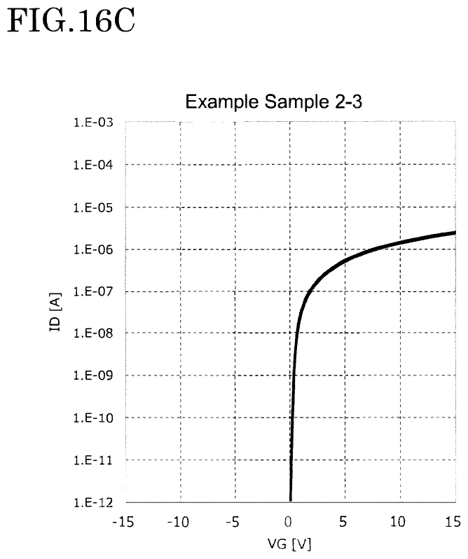

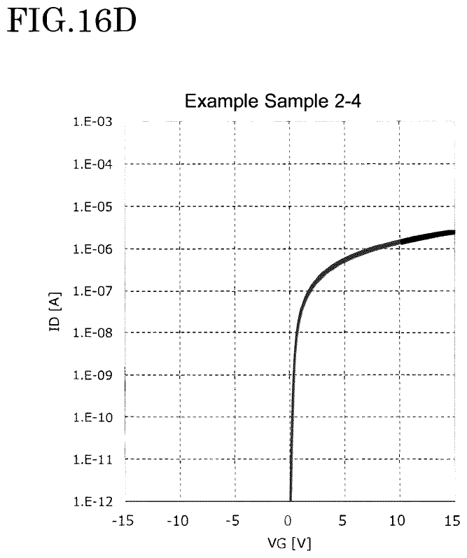

FIGS. 15A to 15D are graphs showing the electrical characteristics of the Example Samples 1-1 to 1-4, respectively. FIGS. 16A to 16D are graphs showing the electrical characteristics of Example Samples 2-1 to 2-4, respectively. Each of the graphs shown in FIGS. 15A to 15D and 16A to 16D show the electrical characteristics of 26 samples having a channel width W/channel length L=4.5 μm/3.0 μm. The vertical axis of the graph showing the electrical characteristics shows a drain current Id, and the horizontal axis shows a gate voltage Vg. Table 3 shows the conditions for measuring the electrical characteristics of each Sample.

TABLE 3

| | |
|---|---|
| Source-Drain Voltage | 0.1 V |
| Gate Voltage | −15 V to +15 V |
| Measurement Environment | Room Temperature, Dark Room |

As shown in FIGS. 15A to 15D and FIGS. 16A to 16D, in all of the Example Samples 1-1 to 1-4 in which a protective insulating layer including silicon nitride is not provided, and the Example Samples 2-1 to 2-4 in which a protective insulating layer including silicon nitride is provided, the electrical characteristics in which the switching performance is shown and depletion is suppressed are obtained.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of the embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
an oxide insulating layer;
an oxide semiconductor layer on the oxide insulating layer;
a gate insulating layer on and in contact with the oxide semiconductor layer; and
a gate electrode on the gate insulating layer,
wherein the oxide semiconductor layer comprises:
a channel region overlapping the gate electrode; and
source and drain regions that do not overlap the gate electrode,
at an interface between the source and drain regions and the gate insulating layer, a concentration of an impurity on a surface of at least one of the source and drain regions is greater than or equal to 1×10¹⁹ cm⁻³.

2. The semiconductor device according to claim 1, wherein the impurity is one selected from the group consisting of boron, phosphorus, argon, and nitrogen.

3. The semiconductor device according to claim 1,
wherein the oxide semiconductor layer comprises a plurality of metal elements,
one of the plurality of metal elements is indium, and
an atomic ratio of indium to the plurality of metal elements is greater than or equal to 50%.

4. The semiconductor device according to claim 1, wherein the oxide semiconductor layer has a polycrystalline structure.

5. The semiconductor device according to claim 4, wherein a crystal structure of at least one of the source and drain regions is a same as a crystal structure of the oxide semiconductor layer.

6. The semiconductor device according to claim 1, wherein a sheet resistance of at least one of the source and drain regions is less than or equal to 1×10² kΩ/sq.

7. The semiconductor device according to claim 1, wherein the oxide insulating layer comprises aluminum oxide.

8. The semiconductor device according to claim 1, further comprising source and drain electrodes electrically connected to the source and drain regions, respectively,
wherein the source and drain electrodes are in contact with a surface of the gate insulating layer that is contact with the gate electrode.

9. The semiconductor device according to claim 1, wherein the gate insulating layer comprises a hydrogen trap region that traps hydrogen.

10. The semiconductor device according to claim 9, wherein the hydrogen trap region is formed by the impurity implanted using the gate electrode as a mask

11. The semiconductor device according to claim 10, wherein the impurity is one selected from the group consisting of boron, phosphorus, argon, and nitrogen.
